(19) United States
(12) Patent Application Publication
(10) Pub. No.: US 2013/0127056 A1
(43) Pub. Date: May 23, 2013

(54) SEMICONDUCTOR DEVICES INCLUDING DUAL DAMASCENE METALLIZATION STRUCTURES

(71) Applicant: Samsung Electronics Co., Ltd., Suwon-si (KR)

(72) Inventors: Jong-ho Yun, Suwon-si (KR); Gil-heyun Choi Choi, Seoul (KR); Sukasa Matsudat, Seongnam-si (KR); Eun-ji Jung, Hwaseong-si (KR)

(73) Assignee: Samsung Electronics Co., Ltd., Suwon-si (KR)

(21) Appl. No.: 13/669,681

(22) Filed: Nov. 6, 2012

(30) Foreign Application Priority Data
Nov. 21, 2011 (KR) 10-2011-0121732

(51) Int. Cl. H01L 23/52

(52) U.S. Cl. 257/751; 257/E23.141

(57) ABSTRACT

A semiconductor device can include a dual-damascene metallization structure that may provide a reduced resistance by providing barrier layers that are different materials. The semiconductor device can include a device layer and a lower conductive layer that can be electrically connected to the device layer. A lower barrier layer can surround the lower conductive layer and an upper conductive layer can be disposed on the lower conductive layer and can be electrically connected to the lower conductive layer. An upper barrier layer can surround the upper conductive layer and can including material that is different from a material included in the lower barrier layer.

### CROSS-REFERENCE TO RELATED APPLICATIONS

This application claims the benefit of Korean Patent Application No. 10-2011-0121732, filed on Nov. 21, 2011, in the Korean Intellectual Property Office, the disclosure of which is incorporated herein in its entirety by reference.

### BACKGROUND

The inventive concept relates to semiconductor devices, and more particularly, to semiconductor devices including dual damascene metallization structures.

Wires electrically connected to a substrate, or semiconductor devices formed on a substrate, may be formed using damascene technology. The size of wires may be reduced according as the size of the semiconductor device is reduced, and accordingly, the resistance of these wires may increase, thereby degrading the reliability of the semiconductor device.

### SUMMARY

According to some embodiments of the inventive concept, there is provided a semiconductor device that can include a device layer and a lower conductive layer that is electrically connected to the device layer. A lower barrier layer can surround the lower conductive layer and an upper conductive layer can be disposed on the lower conductive layer, and can be electrically connected to the lower conductive layer. An upper barrier layer can surround the upper conductive layer, and can include a material that is different from a material included in the lower barrier layer.

In some embodiments of the inventive concept, the lower barrier layer may be disposed on side walls and a bottom of the lower conductive layer.

In some embodiments of the inventive concept, the upper barrier layer may be disposed on side walls and a part on a bottom of the upper conductive layer.

In some embodiments of the inventive concept, the lower barrier layer may include a conductive material.

In some embodiments of the inventive concept, the lower barrier layer may include ruthenium (Ru), cobalt (Co), or a combination thereof.

In some embodiments of the inventive concept, the upper barrier layer may include an insulating material.

In some embodiments of the inventive concept, the upper barrier layer may include manganese silicon oxide.

In some embodiments of the inventive concept, the semiconductor device may further include a first upper interlayer dielectric surrounding the upper barrier layer, wherein the upper barrier layer may be formed by a heat process that generates a chemical combination between a material included in the first upper interlayer dielectric and a material included in the upper conductive layer.

In some embodiments of the inventive concept, a thickness of the upper barrier layer may be equal to or less than a thickness of the lower barrier layer.

In some embodiments of the inventive concept, the upper conductive layer may have a width that is greater than a width of the lower conductive layer.

In some embodiments of the inventive concept, the lower conductive layer may be a pillar, and the upper conductive layer may be lines.

In some embodiments of the inventive concept, the lower conductive layer and the upper conductive layer may form a single body structure.

In some embodiments of the inventive concept, the upper barrier layer may disposed on the lower barrier layer, and the upper barrier layer may have a curved end portion.

In some embodiments of the inventive concept, a lowermost surface of the upper barrier layer may be disposed at a lower level than that of an uppermost surface of the lower barrier layer.

According to an aspect of the inventive concept, there is provided a semiconductor device including a dual-damascene metallization structure, wherein the dual-damascene metallization structure may include a conductive layer and a lower barrier layer that surrounds a lower portion of the conductive layer, and is conductive. An upper barrier layer can surround an upper portion of the conductive layer, and is on the lower barrier layer, and has an insulating property.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a semiconductor device according to embodiments of the present inventive concept;

FIG. 2 is a cross-sectional view of the semiconductor device taken along line II-II of FIG. 1;

FIGS. 3 through 12 are cross-sectional views illustrating methods of forming a semiconductor device according to embodiments of the present inventive concept;

FIGS. 13 through 19 are cross-sectional views illustrating methods of forming a semiconductor device according to embodiments of the present inventive concept;

FIG. 20 is an enlarged cross-sectional view showing a structure of a first upper barrier layer on a first lower conductive layer shown in FIG. 1;

FIG. 21 is a plan view of a memory module including the semiconductor device according to embodiments of the present inventive concept;

FIG. 22 is a schematic diagram showing a memory card according to an embodiment of the present inventive concept;

FIG. 23 is a schematic block diagram of a system according to an embodiment of the present inventive concept; and

FIG. 24 is a perspective view of an electronic device in which the semiconductor device fabricated according to the embodiment of the present inventive concept is included.

### DETAILED DESCRIPTION OF THE EMBODIMENTS ACCORDING TO THE INVENTIVE CONCEPT

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity. As used herein, the term “and/or” includes any and all combinations of one or more of the associated listed items.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

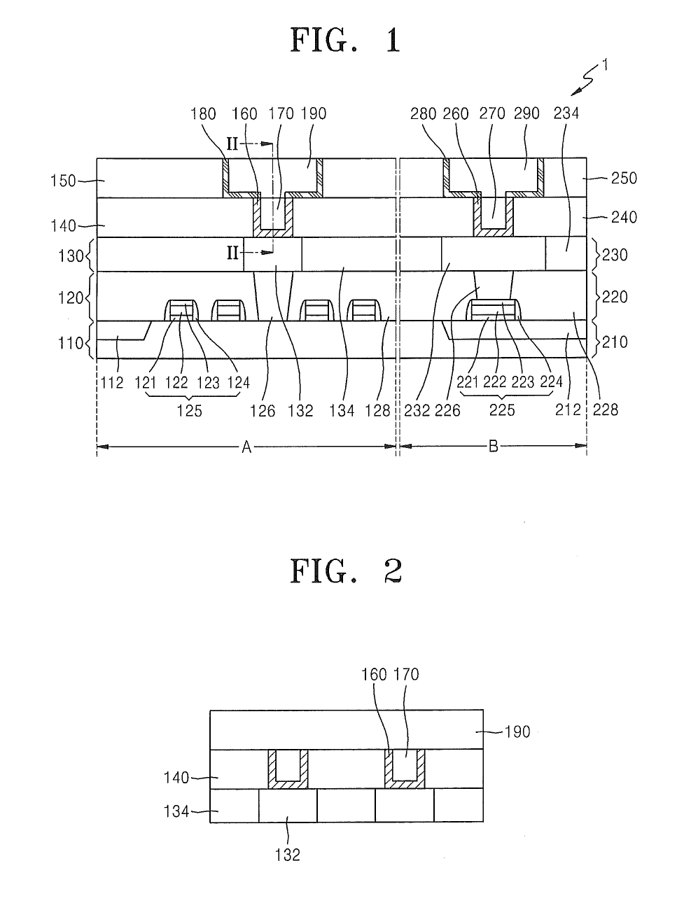

FIG. 1 is a cross-sectional view of a semiconductor device 1 according to embodiments of the present inventive concept, and FIG. 2 is a cross-sectional view of the semiconductor device 1 taken along line II-II of FIG. 1.

Referring to FIG. 1, the semiconductor device 1 may include a region A and a region B. For example, the region A may be a cell region including memory structures, and the region B may be a peripheral region including peripheral circuits.

Hereinafter, a structure of the region A in the semiconductor device 1 will be described as follows.

The semiconductor device 1 may include a first substrate 110, a first device layer 120, a first lower wiring layer 130, a first lower interlayer dielectric 140, and a first upper interlayer dielectric 150.

The first substrate 110 may include a semiconductor material such as silicon or silicon-germanium, and may include an epitaxial layer, a silicon-on-insulator (SOI) layer, and/or a semiconductor-on-insulator (SEOI) layer. The first substrate 110 may include word lines, bit lines, or other semiconductor devices. The first substrate 110 may include a first device isolation layer 112.

The first device layer 120 may be disposed on the first substrate 110. The first device layer 120 may include a first transistor 125 and a first plug 126 that may be electrically connected to the first transistor 125. In addition, the first device layer 120 may further include a first lower insulating layer 128 that surrounds the first transistor 125 and the first plug 126.

The first transistor 125 may include a gate insulating layer 121, a gate electrode 122, a capping layer 123, and a spacer 124. Although the first transistor 125 is disposed on an active area of the first substrate 110 in FIG. 1, the present inventive concept is not limited thereto. For example, the first transistor 125 may be disposed on the first device isolation layer 112 of the first substrate 110. The first device layer 120 may be disposed on the cell region, and may include, for example, a dynamic random access memory (DRAM) device, a flash memory device, or a complementary metal-oxide semiconductor (CMOS) image sensor (CIS) device.

The first lower wiring layer 130 may be disposed on the first device layer 120. The first lower wiring layer 130 may include a first insulation portion 134 and a first conductive portion 132. The first conductive portion 132 may include copper (Cu), tungsten (W), or a combination thereof. The first conductive portion 132 may be electrically connected to the first plug 126, and accordingly may be electrically connected to the first transistor 125. The first conductive portion 132 may function as an additional lower wire, or may function as an extension of the first plug 126.

The first lower interlayer dielectric 140 and the first upper interlayer dielectric 150 may be sequentially disposed on the first lower wiring layer 130. The first lower interlayer dielectric 140 and the first upper interlayer dielectric 150 may include, for example, oxide, nitride, or oxynitride, for example, silicon oxide, silicon nitride, or silicon oxynitride. The first lower interlayer dielectric 140 and the first upper interlayer dielectric 150 may include the same material or different materials from each other.

The first lower interlayer dielectric 140 may include a first lower barrier layer 160. A first lower conductive layer 170 may be filled in the first lower barrier layer 160. The first lower barrier layer 160 may surround the first lower conductive layer 170. That is, a bottom and opposite side walls of the first lower conductive layer 170 may be surrounded by the first lower barrier layer 160, and accordingly, the first lower conductive layer 170 may be separated from the first lower interlayer dielectric 140 so as not to contact the first lower interlayer dielectric 140. The first lower barrier layer 160 may prevent the material forming the first lower conductive layer 170 from dispersing toward the first lower wiring layer 130 and/or the first lower interlayer dielectric 140. The first lower barrier layer 160 may be conductive, and thus may reduce ohmic resistance of the first lower barrier layer 170 and the first conductive portion 132. The first lower barrier layer 160 may include ruthenium (Ru), cobalt (Co), or a combination thereof (for example, an alloy or a stacked structure).

The first upper interlayer dielectric 150 may include a first upper barrier layer 180. A first upper conductive layer 190 may filled a portion that is defined by the first upper barrier layer 180. The first upper barrier layer 180 may surround the first upper conductive layer 190. That is, opposite side walls and a part of a bottom of the first upper conductive layer 190 may be surrounded by the first upper barrier layer 180, and accordingly, the first upper conductive layer 190 may be separated from the first upper interlayer dielectric 150 so as not to contact the first upper interlayer dielectric 150. The first upper barrier layer 180 may prevent the material forming the first upper conductive layer 190 from dispersing to the first lower interlayer dielectric 140 and/or the first upper interlayer dielectric 150. The first upper barrier layer 180 may include an insulating material, for example, an oxide material. The first upper barrier layer 180 may include manganese (Mn) or silicon (Si), for example, manganese silicon oxide (MnSiₓO_{y}, 0<x<1, 0<y<1). Otherwise, the first upper barrier layer 180 may include vanadium (V) instead of manganese (Mn), for example, vanadium silicon oxide material.

The first upper barrier layer 180 may be formed by a heat process, and may be formed by chemically combining materials included in the first upper interlayer dielectric 150 and in the first upper conductive layer 190. For example, the first upper barrier layer 180 may include the manganese silicon oxide that is formed by chemically combining silicon and oxygen included in the first upper interlayer dielectric 150 and the manganese included in the first upper conductive layer 190 due to the heat process.

A thickness of the first upper barrier layer 180 may be equal to or less than a thickness of the first lower barrier layer 160. The first lower barrier layer 160 may have a thickness ranging from about 1 nm to about 20 nm. The first upper barrier layer 180 may have a thickness ranging from about 1 nm to about 10 nm, for example, from 2 nm to 5 nm.

The first lower conductive layer 170 may include copper (Cu), and may further include manganese (Mn). The first upper conductive layer 190 may include copper (Cu), and may further include manganese (Mn). The first lower conductive layer 170 and the first upper conductive layer 190 may be physically and/or electrically connected to each other. The first lower conductive layer 170 and the first upper conductive layer 190 may form a one body structure (i.e., unitary body structure). The first lower conductive layer 170 and the first upper conductive layer 190 may include the same material or different materials from each other. The first upper conductive layer 190 may have a greater width than that of the first lower conductive layer 170. The first lower conductive layer 170 may have a width ranging from about 5 nm to about 20 nm, and the first upper conductive layer 190 may have a width ranging from about 10 nm to about 50 nm.

Referring to FIG. 2, the first lower conductive layer 170 may function as a plug that is electrically connected to the first conductive portion 132, and may be formed as a pillar such as a cylinder or a polygonal pillar. On the other hand, the first upper conductive layer 190 may be formed as lines and may be electrically connected to outside. Accordingly, the first lower conductive layer 170 and the first upper conductive layer 190 may form a dual-damascene metallization structure.

Hereinafter, the region B of the semiconductor device 1 will be described as follows.

The semiconductor device 1 may include a second substrate 210, a second device layer 220, a second lower wiring layer 230, a second lower interlayer dielectric 240, and a second upper interlayer dielectric 250.

The second substrate 210 may be the same structure as the first substrate 110. In addition, the second substrate 210 may further include word lines, bit lines, and/or other semiconductor devices. The second substrate 210 may include a second device isolation layer 212.

The second device layer 220 may be disposed on the second substrate 210. The second device layer 220 may include a second transistor 225 and a second plug 226 that is electrically connected to the second transistor 225. In addition, the second device layer 220 may include a second lower insulating layer 228 that surrounds the second transistor 225 and the second plug 226.

The second transistor 225 may include a gate insulating layer 221, a gate electrode 222, a capping layer 223, and a spacer 224. In FIG. 1, the second transistor 225 is disposed on the second device isolation layer 212, however, the present inventive concept is not limited thereto. The second transistor 225 may be disposed on an active region of the second substrate 210. The second device layer 220 may be disposed on a peripheral circuit region, and may include peripheral circuit devices of the semiconductor device, for example. The first device layer 120 and the second device layer 220 may be disposed at the same plane level or at different plane levels.

The second lower wiring layer 230 may be disposed on the second device layer 220. The second lower wiring layer 230 may include a second insulating portion 234 and a second conductive portion 232. The second conductive portion 232 may include copper (Cu), tungsten (W), or a combination thereof. The second conductive portion 232 may be electrically connected to the second plug 226, and accordingly may be electrically connected to the second transistor 225. The second conductive portion 232 may function as a lower wire or an extension of the second plug 226. The first lower wiring layer 130 and the second lower wiring layer 230 may be disposed at the same plane level or at different plane levels.

The second lower interlayer dielectric 240 and the second upper interlayer dielectric 250 may be sequentially disposed on the second lower wiring layer 230. The second lower interlayer dielectric 240 and the second upper interlayer dielectric 250 may include, for example, oxide, nitride, or oxynitride, for example, silicon oxide, silicon nitride, or silicon oxynitride. The second lower interlayer dielectric 240 and the second upper interlayer dielectric 250 may include the same material or different materials from each other. The first lower interlayer dielectric 140 and the second lower interlayer dielectric 240 may be formed through the same process or different processes from each other, and may be disposed at the same plane level or at different plane levels. The first upper interlayer dielectric 150 and the second upper interlayer dielectric 250 may be disposed at the same plane level or at different plane levels.

The second lower interlayer dielectric 240 may include a second lower barrier layer 260. A second lower conductive layer 270 may be filled in the second lower barrier layer 260. The second lower barrier layer 260 may surround the second lower conductive layer 270. That is, a bottom and opposite side walls of the second lower conductive layer 270 may be surrounded by the second lower barrier layer 260, and accordingly, the second lower conductive layer 270 may be separated from the second lower interlayer dielectric 240 so as not to contact the second lower interlayer dielectric 240. The second lower barrier layer 260 may prevent the material forming the second lower conductive layer 270 from dispersing toward the second lower wiring layer 230 and/or the second lower interlayer dielectric 240. The second lower barrier layer 260 may be conductive, and thus may reduce the ohmic resistance of the second lower conductive layer 270 and the second conductive portion 232. The second lower barrier layer 260 may include ruthenium (Ru), cobalt (Co), or a combination thereof. The second lower conductive layer 270 may be electrically connected to the second transistor 225 in the second device layer 220.

The second upper interlayer dielectric 250 may include a second upper barrier layer 280. A second upper conductive layer 290 may be filled in the second upper barrier layer 280. The second upper barrier layer 280 may surround the second upper conductive layer 290. That is, opposite side walls and a part of a bottom of the second upper conductive layer 290 may be surrounded by the second upper barrier layer 280, and accordingly, the second upper conductive layer 290 may be separated from the second upper interlayer dielectric 250 so as not to contact the second upper interlayer dielectric 250. The second upper barrier layer 280 may prevent the material forming the second upper conductive layer 290 from dispersing toward the second lower interlayer dielectric 240 and/or the second upper interlayer dielectric 250. The second upper barrier layer 280 may include an insulating material, for example, an oxide material. The second upper barrier layer 280 may include manganese (Mn) or silicon (Si), for example, manganese silicon oxide (MnSiₓO_{y}, 0<x<1, 0<y<1). Otherwise, the second upper barrier layer 280 may include vanadium (V) instead of manganese (Mn), for example, vanadium silicon oxide material.

The second upper barrier layer 280 may be formed by a heat process, or may be formed by chemically combining the material included in the second upper interlayer dielectric 250 and the material included in the second upper conductive layer 290. For example, the second upper barrier layer 280 may include manganese silicon oxide (MnSiₓO_{y}, 0<x<1, 0<y<1) that is formed by chemically combining silicon and oxygen included in the second upper interlayer dielectric 250 and the manganese included in the second upper conductive layer 290 due to the heat process.

The second upper barrier layer 280 may have a thickness that is equal to or less than that of the second lower barrier layer 260. Thickness of the second lower barrier layer 260 may be equal to or greater than that of the first lower barrier layer 160. The thickness of the second upper barrier layer 280 may be equal to or greater than that of the first upper barrier layer 180.

The second lower conductive layer 270 may include copper (Cu), for example, and may further include manganese (Mn). The second upper conductive layer 290 may include copper (Cu), and may further include manganese (Mn), for example. The second lower conductive layer 270 and the second upper conductive layer 290 may be physically and/or electrically connected to each other. The second lower conductive layer 270 and the second upper conductive layer 290 may form a one body structure (i.e., unitary body structure). The second lower conductive layer 270 and the second upper conductive layer 290 may include the same material or different materials from each other. The second upper conductive layer 290 may have a width that is greater than that of the second lower conductive layer 270. The second lower conductive layer 270 may have a width that is equal to or greater than that of the first lower conductive layer 170. Thickness of the second upper conductive layer 290 may be equal to or greater than that of the first upper conductive layer 190.

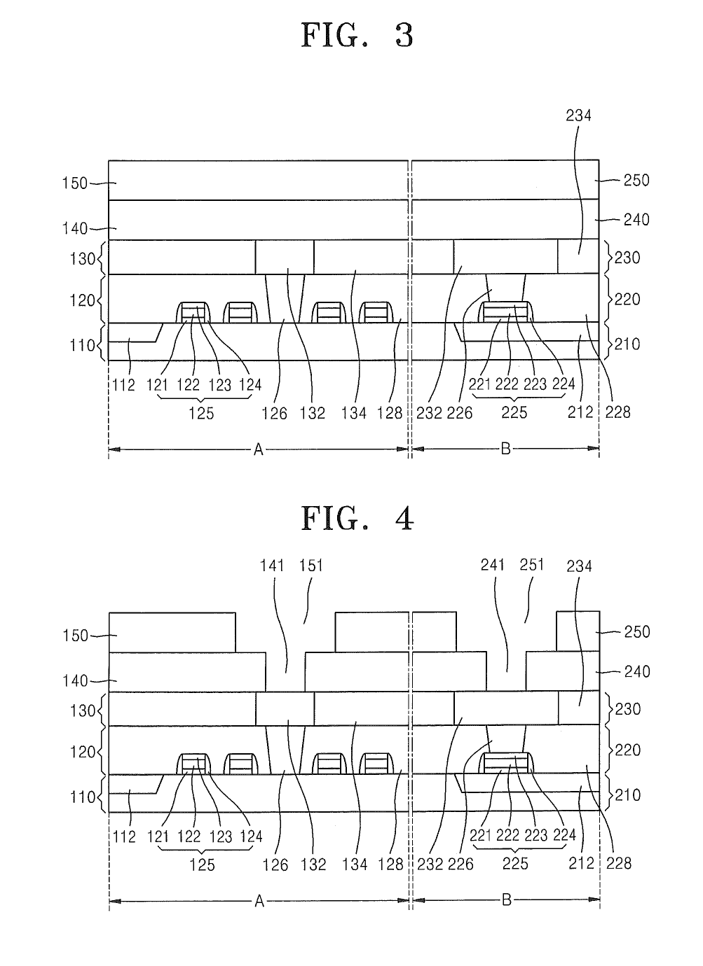

FIGS. 3 through 12 are cross-sectional views illustrating methods of forming the semiconductor device 1 according to an embodiment of the present inventive concept. In the drawings, a region A may be a cell region and a region B may be a peripheral region. In the regions A and B, the forming of the structures may be performed simultaneously or separately.

Referring to FIG. 3, the first substrate 110 corresponding to the region A and the second substrate 210 corresponding to the region B are prepared. The first and second substrates 110 and 210 may be the same structure.

The first device layer 120 including the first transistor 125 and the first plug 126 is formed on the first substrate 110. In addition, the second device layer 220 including the second transistor 225 and the second plug 226 is formed on the second substrate 210. The first and second device layers 120 and 220 may be formed through the same process or different processes from each other.

The first lower wiring layer 130 including the first insulating portion 134 and the first conductive portion 132 is formed on the first device layer 120. In addition, the second lower wiring layer 230 including the second insulating portion 234 and the second conductive portion 232 is formed on the second device layer 220. The first and second lower wiring layers 130 and 230 may be formed through the same process or different processes from each other.

The first lower interlayer dielectric 140 is formed on the first lower wiring layer 130. In addition, the second lower interlayer dielectric 240 is formed on the second lower wiring layer 230. The first and second lower interlayer dielectrics 140 and 240 may be formed through the same process or different processes from each other. The first and second lower interlayer dielectrics 140 and 240 may be formed by using a thermal oxidation process, a chemical vapor deposition (CVD) process, a plasma enhanced CVD (PECVD) process, a sputtering process, or an atomic layer deposition (ALD) process.

The first upper interlayer dielectric 150 is formed on the first lower interlayer dielectric 140. In addition, the second upper interlayer dielectric 250 is formed on the second lower interlayer dielectric 240. The first and second upper interlayer dielectrics 150 and 250 may be formed through the same process or different processes from each other. The first and second upper interlayer dielectrics 150 and 250 may be formed using a thermal oxidation process, a CVD process, a PECVD process, a sputtering process, or an ALD process.

The first lower interlayer dielectric 140 and the first upper interlayer dielectric 150 may include the same material or different materials from each other. The second lower interlayer dielectric 240 and the second upper interlayer dielectric 250 may include the same material or different materials from each other. In addition, an etch stop layer may be disposed between the first lower interlayer dielectric 140 and the first upper interlayer dielectric 150. Also, an etch stop layer may be disposed between the second lower interlayer dielectric 240 and the second upper interlayer dielectric 250.

Referring to FIG. 4, some parts of the first lower interlayer dielectric 140 and the first upper interlayer dielectric 150 are removed to form a first lower recess region 141 and a first upper recess region 151 that expose the first conductive portion 132. The first lower recess region 141 may be disposed in the first lower interlayer dielectric 140, and the first upper recess region 151 may be disposed in the first upper interlayer dielectric 150. In addition, some parts of the second lower interlayer dielectric 240 and the second upper interlayer dielectric 250 are removed to form a second lower recess region 241 and a second upper recess region 251 that expose the second conductive portion 232. The second lower recess region 241 may be disposed in the second lower interlayer dielectric 240, and the second upper recess region 251 may be disposed in the second upper interlayer dielectric 250.

The first lower recess region 141, the first upper recess region 151, the second lower recess region 241, and the second upper recess region 251 may be formed by a photolithography and an etching process. The first and second lower recess regions 141 and 241 may be formed through the same process or different processes. The first upper recess region 151 and the second upper recess region 251 may be formed through the same process or different processes. The first lower recess region 141, the first upper recess region 151, the second lower recess region 241, and the second upper recess region 251 may be formed by a trench first via last (TFVL) process or a via first trench last (VFTL) process.

The first lower recess region 141 and the second lower recess region 241 may be formed as, for example, holes. For example, the first lower recess region 141 may provide a space for forming the first lower conductive layer 170 formed as a pillar shown in FIG. 2. The first upper recess region 151 and the second upper recess region 251 may be formed as line type trenches. For example, the first upper recess region 151 may provide a space for forming the first upper conductive layer 190 formed as a line as shown in FIG. 2.

Referring to FIG. 5, a first lower barrier material layer 161 is formed on an uppermost surface of the first upper interlayer dielectric 150, side walls of the first upper recess region 151, and side walls and a bottom of the first lower recess region 141. In addition, a second lower barrier material layer 261 is formed on an uppermost surface of the second upper interlayer dielectric 250, side walls of the second upper recess region 251, and side walls and a bottom of the second lower recess region 241. The first and second lower barrier material layers 161 and 261 may be formed by using a thermal oxidation process, a CVD process, a PECVD process, a sputtering process, or an ALD process. In addition, the first and second lower barrier material layers 161 and 261 may be formed through the same process or different processes.

The first and second lower barrier material layers 161 and 261 may include ruthenium (Ru), cobalt (Co), or a combination thereof. The first and second lower barrier material layers 161 and 261 may include the same material or different materials. In addition, the first and second lower barrier material layers 161 and 261 may include tantalum (Ta), tantalum nitride (TaN), titanium (Ti), titanium nitride (TiN), tungsten (W), tungsten nitride (WN), ruthenium (Ru), cobalt (Co), or a combination thereof (for example, an alloy or a stacked structure).

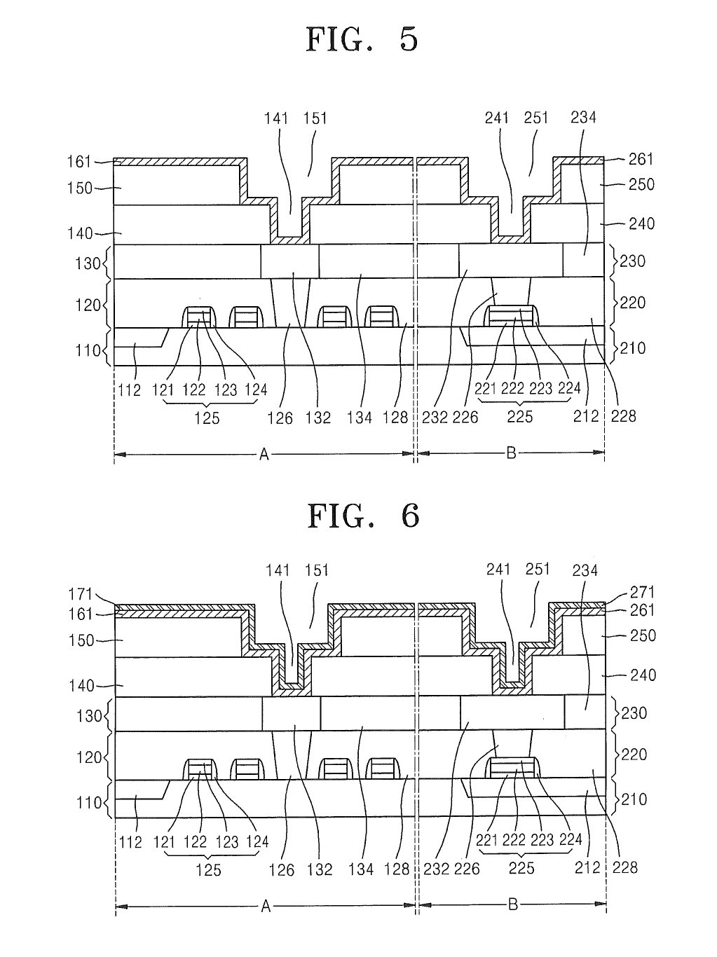

Referring to FIG. 6, a first lower seed layer 171 is formed on the first lower barrier material layer 161. In addition, a second lower seed layer 271 is formed on the second lower barrier layer 261. The first and second lower seed layers 171 and 271 may be formed by using a physical vapor deposition (PVD) process, a CVD process, a PECVD process, or an ALD process. The first and second lower seed layers 171 and 271 may be formed through the same process or different processes. The first and second lower seed layers 171 and 271 may include Cu. In addition, the first and second lower seed layers 171 and 271 may include platinum (Pt), palladium (Pd), nickel (Ni), gold (Au), silver (Ag), or ruthenium (Ru).

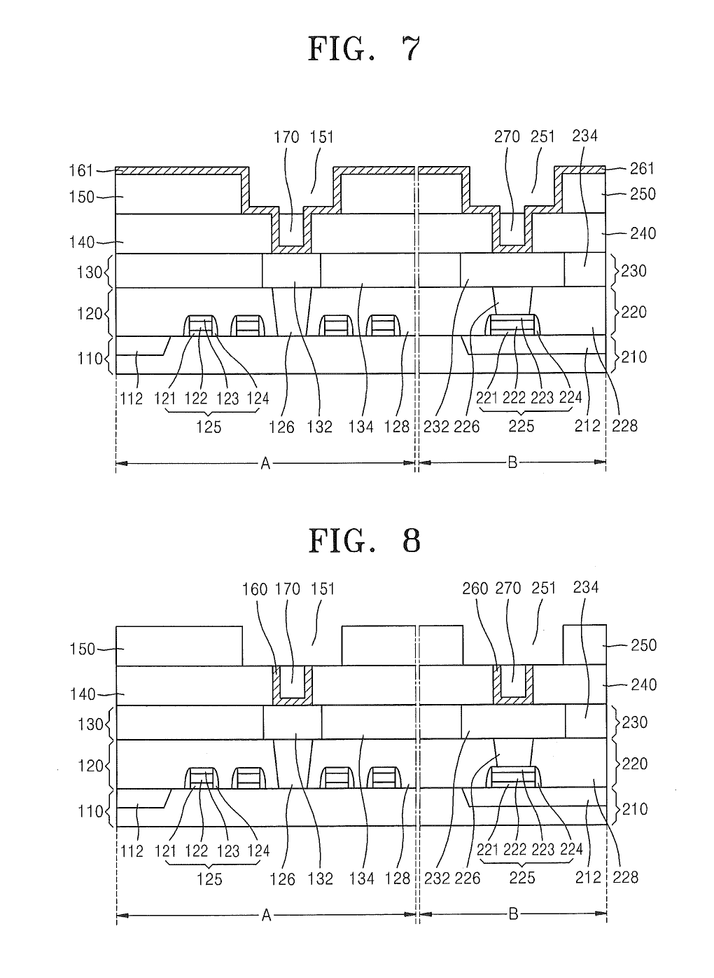

Referring to FIG. 7, the first lower seed layer 171 is reflowed to form the first lower conductive layer 170. Accordingly, the first lower conductive layer 170 may fill in the first lower recess region 141. In addition, the first lower seed layer 171 disposed outside the first lower recess region 141 may flow to fill the first lower recess region 141 and may be otherwise removed. Otherwise, the remaining first lower seed layer 171 disposed outside the first lower recess region 141 may be removed using an additional etching process. Also, the second lower seed layer 271 is reflowed to form the second lower conductive layer 270. Accordingly, the second lower conductive layer 270 may fill in the second lower recess region 241. In addition, the second lower seed layer 271 disposed outside the second lower recess region 241 may flow to fill the second lower recess region 241 and may otherwise be removed. Otherwise, the second lower seed layer 271 disposed outside the second lower recess region 241 may be removed by using an additional etching process.

The first lower conductive layer 170 and the second lower conductive layer 270 may be formed through the same process or different processes. The reflow process may be performed by using the heat process. The reflow process may be performed within a temperature range from 200° C. to 500° C., for example, from 300° C. to 400° C. In addition, the reflow process may be performed under a vacuum atmosphere, a reduced atmosphere, or an oxidizing atmosphere. In addition, the reflow process may be performed using a plasma process, and may use argon plasma, nitrogen plasma, or oxygen plasma. Otherwise, the reflow process may be performed by using laser, for example, nitrogen laser or helium laser.

Processes shown in FIGS. 6 and 7 may be realized as a contiguous or single process. That is, on forming the first lower seed layer 171, the first lower seed layer 171 is reflowed to form the first lower conductive layer 170. In addition, on forming the second lower seed layer 271, the second lower seed layer 271 is reflowed to form the second lower conductive layer 270. For example, by performing the processes shown in FIGS. 6 and 7 within a temperature range of 200° C. to 500° C. , the first lower seed layer 171 may be reflowed as soon as it is formed, and the second lower seed layer 271 may be reflowed as soon as it is formed. Also, when the first lower barrier material layer 161 and the second lower barrier material layer 261 include ruthenium (Ru), the reflow process may be performed more easily.

Due to the reflow process, the first and second lower conductive layers 170 and 270 may not include undesired voids or may reduce a density of the voids. In addition, the materials forming the first and second lower conductive layers 170 and 270 have large grains due to growth of the grains, and thus resistance values of the first and second lower conductive layers 170 and 270 may be reduced.

Referring to FIG. 8, a part of the first lower barrier material layer 161 is removed to form the first lower barrier layer 160 surrounding the first lower conductive layer 170. The uppermost surfaces of the first lower barrier layer 160 and the first lower conductive layer 170 may be exposed in the first upper recess region 151. In addition, a part of the second lower barrier material layer 261 is removed to form the second lower barrier layer 260 surrounding the second lower conductive layer 270. The uppermost surfaces of the second lower barrier layer 260 and the second lower conductive layer 270 may be exposed in the second upper recess region 251. The first and second lower barrier material layers 161 and 261 may be removed by an etch-back process, and may be removed in the same process or different processes.

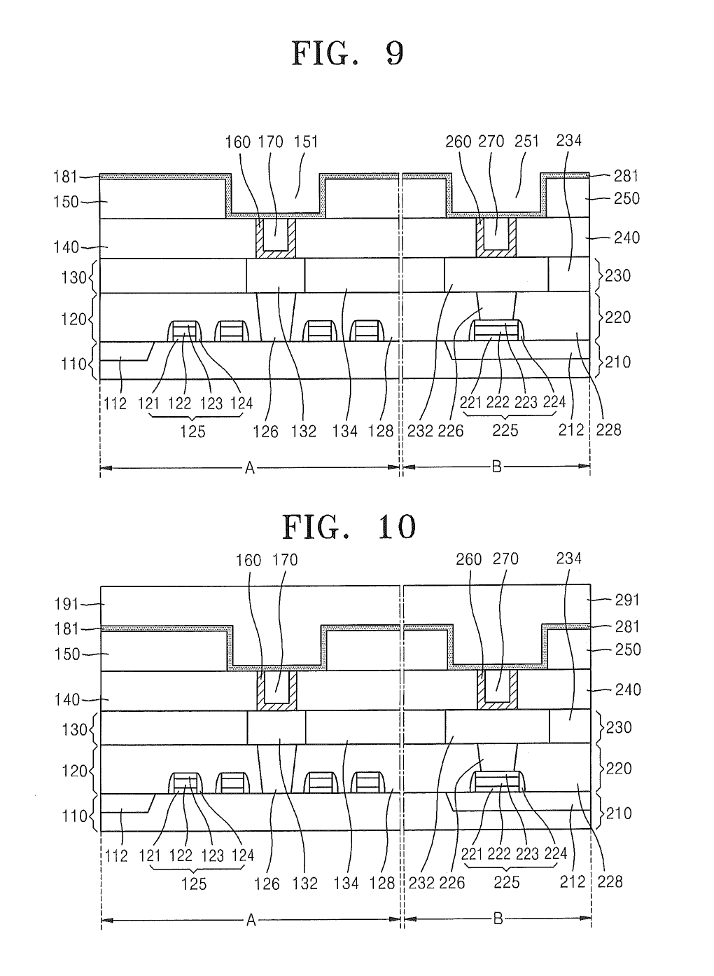

Referring to FIG. 9, a first upper seed layer 181 is formed on the uppermost surface of the first upper interlayer dielectric 150 and side walls and a bottom of the first upper recess region 151. In addition, a second upper seed layer 281 is formed on the uppermost surface of the second upper interlayer dielectric 250 and side walls and a bottom of the second upper recess region 251. The first and second upper seed layers 181 and 281 may be formed by using a PVD process, a CVD process, a PECVD process, or an ALD process. The first and second upper seed layers 181 and 281 may be formed through the same process or different processes. The first and second upper seed layers 181 and 281 may include copper (Cu) and manganese (Mn). In another embodiment, the first and second upper seed layers 181 and 281 may include vanadium (V) instead of manganese (Mn),

Referring to FIG. 10, a first metal layer 191 is formed on the first upper seed layer 181. The first metal layer 191 may fill in the first upper recess region 151. The first upper seed layer 181 may promote the formation of the first metal layer 191. In addition, a second metal layer 291 is formed on the second upper seed layer 281. The second metal layer 291 may fill in the second upper recess region 251. The second upper seed layer 281 may promote the formation of the second metal layer 291. The first and second metal layers 191 and 291 may be formed by an electroplating method, a PVD process, a CVD process, a PECVD process, or an ALD process. The first and second metal layers 191 and 291 may be formed through the same process or different processes. The first and second metal layers 191 and 291 may include copper (Cu). Moreover, the first and second metal layers 191 and 291 may include platinum (Pt), palladium (Pd), nickel (Ni), gold (Au), silver (Ag), or ruthenium (Ru). Since the first lower conductive layer 170 includes the grains that are grown by the reflow process, the first upper seed layer 181 and the first metal layer 191 formed on the first lower conductive layer 170 are consistently grown with respect to the grown grains, and thus may have relatively large grains. Accordingly, the resistance value of the first metal layer 191 may be reduced. In particular, the grains of the first lower conductive layer 170 grown by according to the present inventive concept may be larger than grains formed by the conventional method such as a PVD-barrier layer, and thus the resistance value of the first lower conductive layer 170 may be reduced, and moreover the resistance value of the wiring layer including the first upper conductive layer 190 and the first lower conductive layer 170 may be greatly reduced. Also, since the second lower conductive layer 270 has the grains grown by the reflow, the second upper seed layer 281 and the second metal layer 291 formed on the second lower conductive layer 270 may have relatively large grains that are consistently grown with respect to the grown grains, and accordingly the resistance value of the second metal layer 291 may be reduced. In particular, the grains of the second lower conductive layer 270 grown according to the present inventive concept may be larger than grains formed by the conventional method such as a PVD-barrier layer, and thus the resistance value of the second lower conductive layer 270 may be greatly reduced, and moreover the resistance value of the wiring layer consisting of the second upper conductive layer 290 and the second lower conductive layer 270 may be reduced.

Referring to FIG. 11, the structure shown in FIG. 10 is thermally processed. The thermal process may be performed within a temperature range of 200° C. to 500° C., for example, 300° C. to 400° C. . Accordingly, the first upper seed layer 181 is changed to a first upper barrier material layer 182. The first upper barrier material layer 182 may be formed when atoms included in the first upper seed layer 181 combine with atoms included in the first upper interlayer dielectric 150. For example, the first upper barrier material layer 182 may be formed when manganese (Mn) included in the first upper seed layer 181 combines with Si and 0 included in the first upper interlayer dielectric 150. The first upper barrier material layer 182 may include, for example, manganese silicon oxide (MnSiₓO_{y}, 0<x<1, 0<y<1). Copper included in the first upper seed layer 181 may be moved to the first metal layer 191. In addition, the second upper seed layer 281 is changed into a second upper barrier material layer 282. The second upper barrier material layer 282 may be formed when atoms included in the second upper seed layer 281 combine with atoms included in the second upper interlayer dielectric 250. For example, the second upper barrier material layer 282 may be formed when manganese (Mn) included in the second upper seed layer 281 combines with Si and 0 included in the second upper interlayer dielectric 250. Copper included in the second upper seed layer 281 may be moved to the second metal layer 291.

The first upper seed layer 181 that is disposed directly on the first lower conductive layer 170 may be dispersed in a longitudinal direction or a transverse direction, and may be removed. The above phenomenon may occur when the materials included in the first upper seed layer 181 move to adjacent layers due to the dispersion. For example, copper included in the first upper seed layer 181 may be dispersed to the first lower conductive layer 170 and/or the first metal layer 191. Also, manganese (Mn) included in the first upper seed layer 181 may be dispersed to the first barrier material layer 182. In addition, manganese (Mn) included in the first upper seed layer 181 may be dispersed to the first lower conductive layer 170 and/or the first metal layer 191. In the same manner, the second upper seed layer 281 that is disposed directly on the second lower conductive layer 270 may be dispersed in a longitudinal direction or a transverse direction, and may be removed.

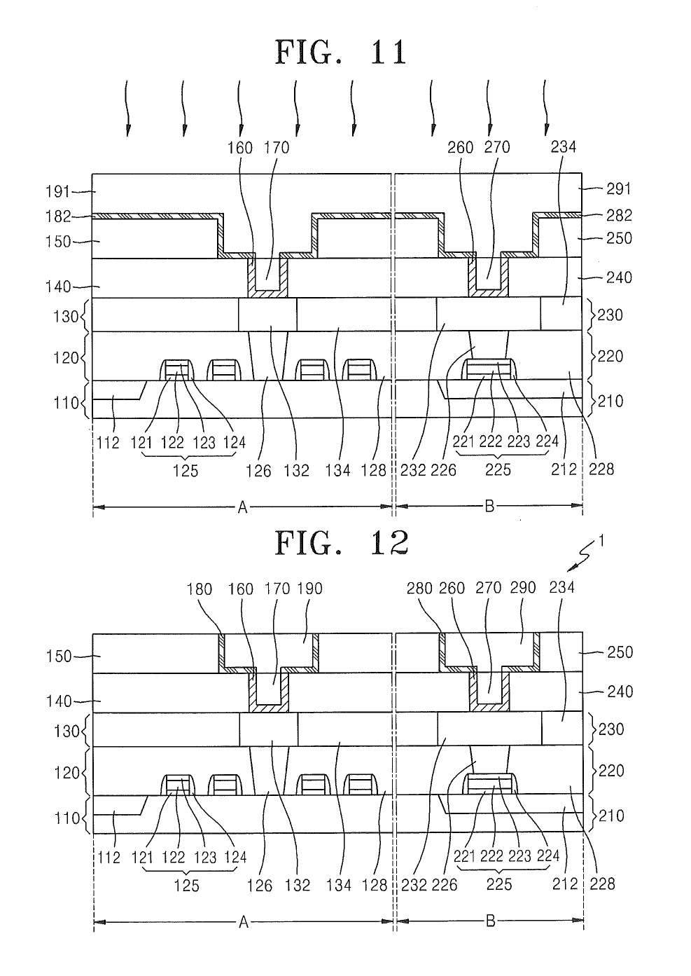

Referring to FIG. 12, the first metal layer 191 and the first upper barrier material layer 182 are planarized by an etch-back or a CMP process to form the first upper conductive layer 190 and the first upper barrier layer 180. In addition, the second metal layer 291 and the second upper barrier material layer 292 are planarized by the etch-back or the CMP process to form the second upper conductive layer 290 and the second upper barrier layer 280.

Since the first upper barrier layer 180 is formed by chemically combining the first upper seed layer 181 and the first upper interlayer dielectric 150 through the thermal process, a relatively thin layer may be obtained compared to the layer formed by a deposition process. For example, the first upper barrier layer 180 may have a thickness that is less than that of the first lower barrier layer 160. Accordingly, the first upper conductive layer 190 may be wider and the resistance value of the first upper conductive layer 190 may be reduced. Also, since the second upper barrier layer 280 is formed by chemically combining the second upper seed layer 281 and the second upper interlayer dielectric 250 through the thermal process, a relatively thin layer may be obtained compared to the layer formed by a deposition process. For example, the second upper barrier layer 280 may have a thickness that is less than that of the second lower barrier layer 260. Accordingly, the second upper conductive layer 290 may be wider and the resistance value of the second upper conductive layer 290 may be reduced.

FIGS. 13 through 19 are cross-sectional views illustrating the semiconductor device 1 according to embodiments of the present inventive concept, and descriptions about the same components as those of the previous embodiments are not provided here.

Referring to FIG. 13, the first substrate 110 on which the first device layer 120, the first lower wiring layer 130, and the first lower interlayer dielectric 140 are formed is prepared. In addition, the second substrate 210 on which the second device layer 220, the second lower wiring layer 230, and the second lower interlayer dielectric 240 are formed is prepared. The first and second substrates 110 and 210 may be the same structure body.

A part of the first lower interlayer dielectric 140 is removed to form the first lower recess portion 141 that exposes the first conductive portion 132. In addition, a part of the second lower interlayer dielectric 240 is removed to form the second lower recess region 241 that exposes the second conductive portion 232.

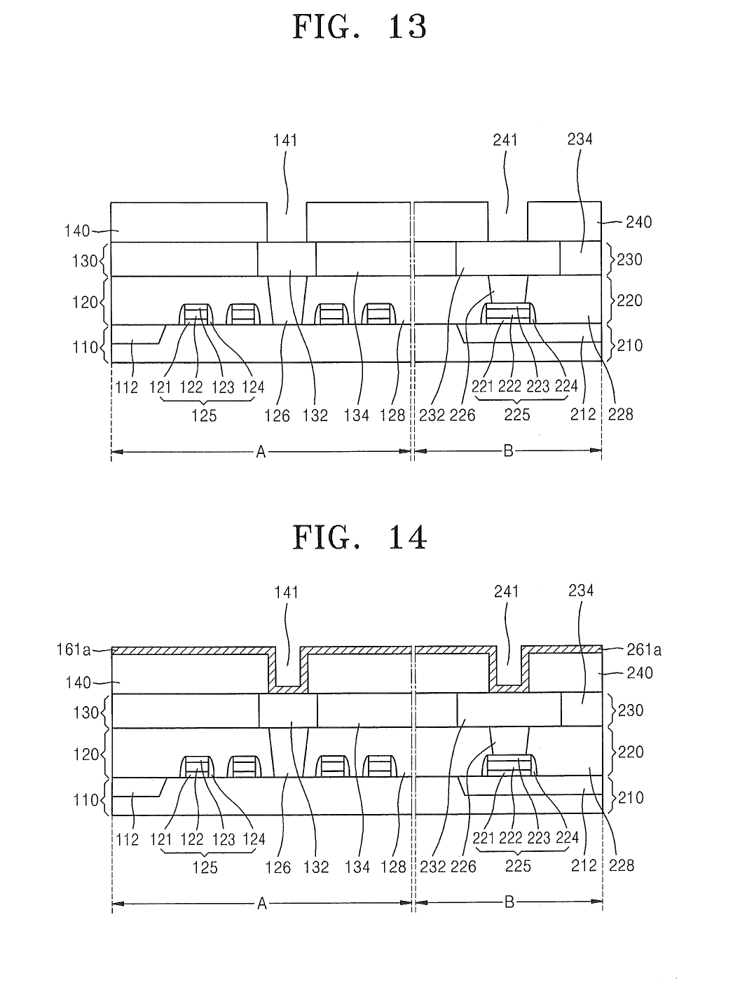

Referring to FIG. 14, a first lower barrier material layer 161a is formed on an uppermost surface of the first lower interlayer dielectric 140 and on side walls and a bottom of the first lower recess region 141. In addition, a second lower barrier material layer 261a is formed on an uppermost surface of the second lower interlayer dielectric 240 and on side walls and a bottom of the second lower recess region 241.

Referring to FIG. 15, a first lower seed layer 171a is formed on the first lower barrier material layer 161a. In addition, a second lower seed layer 271a is formed on the second lower barrier material layer 261a.

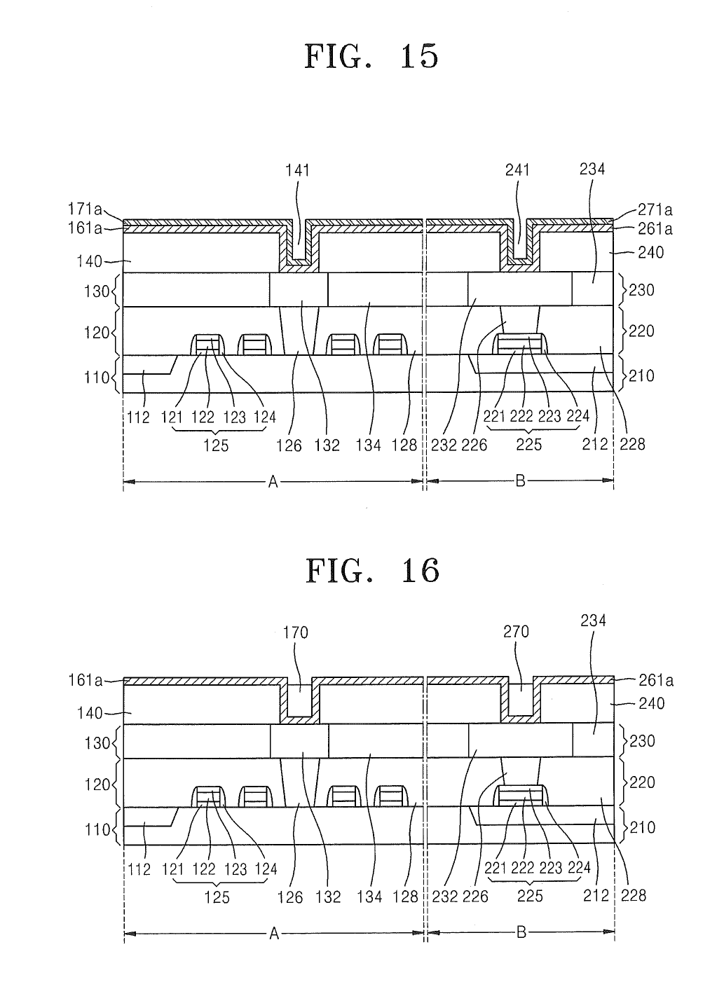

Referring to FIG. 16, the first lower seed layer 171a is reflowed to form the first lower conductive layer 170. Accordingly, the first lower conductive layer 170 may fill in the first lower recess region 141. In addition, the first lower seed layer 171a disposed outside the first lower recess region 141 may flow to fill the first lower recess region 141. Otherwise, the first lower seed layer 171a disposed outside the first lower recess region 141 may be removed by performing an additional etching process. In addition, the second lower seed layer 271a is reflowed to form the second lower conductive layer 270. Accordingly, the second lower conductive layer 270 may fill in the second lower recess region 241. In addition, the second lower seed layer 271a disposed outside the second lower recess region 241 may flow to fill the second lower recess region 241. Otherwise, the second lower seed layer 271 disposed on the other region except for the second lower recess region 241 may be removed by performing an additional etching process.

The processes shown in FIGS. 15 and 16 may be realized as one process (i.e., a continuous or single process). That is, on forming the first lower seed layer 171a, the first lower seed layer 171a is reflowed to form the first lower conductive layer 170. In addition, on forming the second lower seed layer 271a, the second lower seed layer 271a is reflowed to form the second lower conductive layer 270.

Referring to FIG. 17, a part of the first lower barrier material layer 161a is removed to form the first lower barrier layer 160 surrounding the first lower conductive layer. In addition, a part of the second lower barrier material layer 261a is removed to form the second lower barrier layer 260 surrounding the second lower conductive layer 270. The first lower barrier material layer 161a and the second lower barrier material layer 261a may be removed by performing an etch-back process or a CMP process.

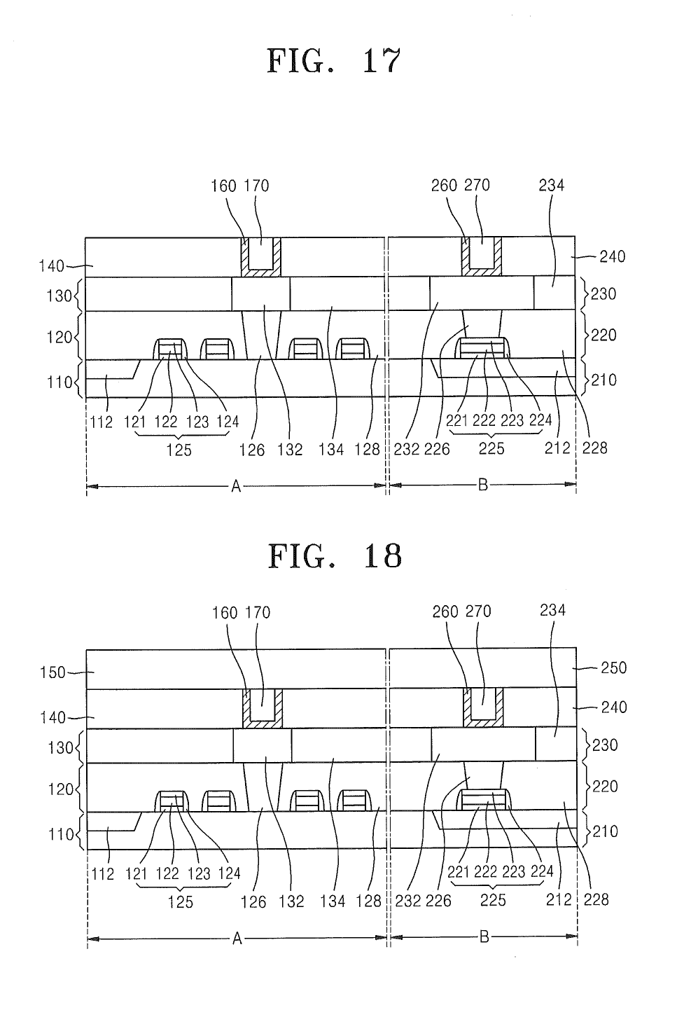

Referring to FIG. 18, the first upper interlayer dielectric 150 is formed on the first lower interlayer dielectric 140. In addition, the second upper interlayer dielectric 250 is formed on the second lower interlayer dielectric 240.

Referring to FIG. 19, a part of the first upper interlayer dielectric 150 is removed to form the first upper recess region 151 that exposes the first lower barrier layer 160 and the first lower conductive layer 170. In addition, a part of the second upper interlayer dielectric 250 is removed to form the second upper recess region 251 that exposes the second lower barrier layer 260 and the second lower conductive layer 270.

Hereinafter, the processes illustrated in FIGS. 9 through 12 are performed.

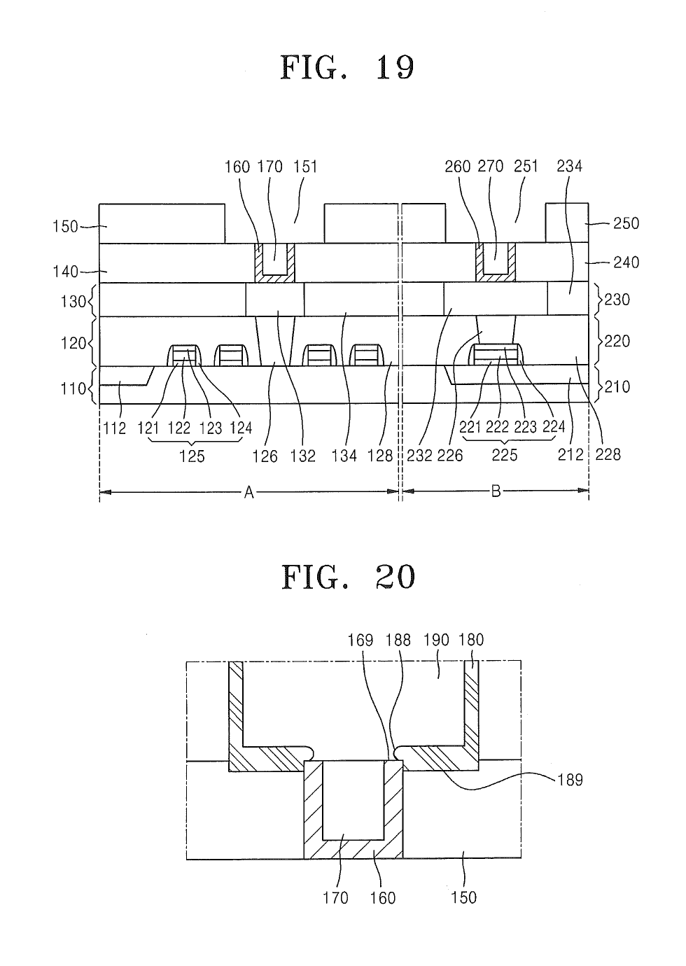

FIG. 20 is an expanded cross-sectional view exemplary showing a structure of the first upper barrier wall 180 formed on the first lower conductive layer 170 shown in FIG. 1.

Referring to FIG. 20, as described with reference to FIG. 11, the material included in the first upper seed layer (181, refer to FIG. 10) may be dispersed into the first upper interlayer dielectric 150 due to the heat process. In addition, the materials included in the first upper seed layer 181 disposed in the lower conductive layer 170 may be dispersed into the first lower conductive layer 170 or the first upper conductive layer 190, or toward the first upper interlayer dielectric 150. According to the movement of materials, the first upper barrier layer 180 on the first lower conductive layer 170 may be removed, and the first upper barrier layer 180 may not entirely cover the uppermost surface of the first lower barrier layer 160. In addition, the first upper barrier layer 180 disposed on the first lower barrier layer 160 may have a curved end portion 188. In addition, a lower portion of the first upper barrier layer 180 that is disposed on the first upper interlayer dielectric 150 may contact a side wall of the first lower barrier layer 160. That is, a lowermost surface 189 of the first upper barrier layer 180 may be disposed at a lower level than that of an uppermost surface 169 of the first lower barrier layer 160. In addition, the modification of the first upper barrier layer 180 may be applied to the second upper barrier layer 280.

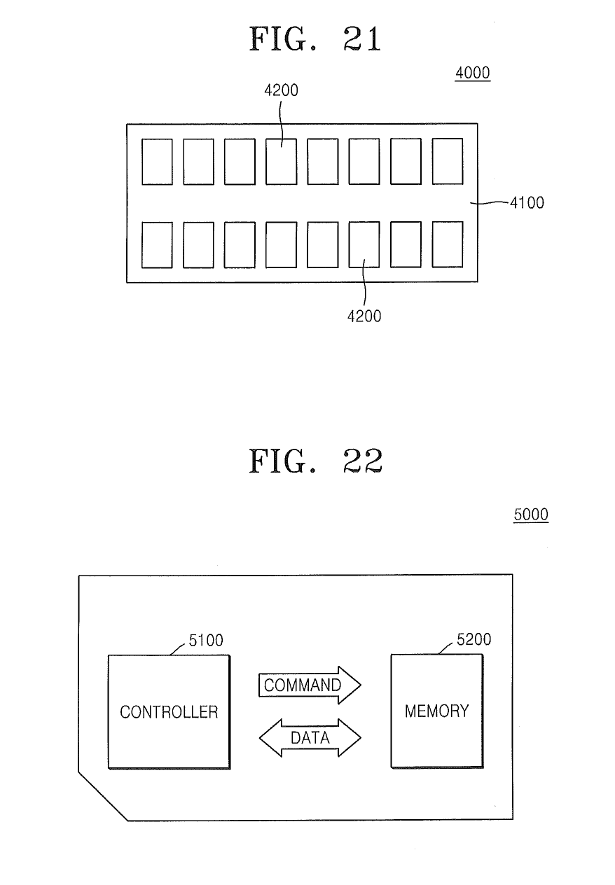

FIG. 21 is a plan view of a memory module 4000 including a semiconductor device, according to exemplary embodiments of the inventive concept.

Referring to FIG. 21, the memory module 4000 includes a printed circuit board 4100 and a plurality of semiconductor packages 4200. The semiconductor packages 4200 may include a semiconductor device formed by a method according to exemplary embodiments of the inventive concept. The memory module 4000 may be a single in-line memory module (SIMM) in which the semiconductor packages 4200 are mounted only on one surface of a printed circuit board, or a dual in-line memory module (DIMM) in which the semiconductor packages 4200 are mounted on both surfaces of a printed circuit board. Also, the memory module 4000 according to embodiments of the inventive concept may be a fully buffered DIMM (FBDIMM) having an advanced memory buffer (AMB) for providing external signals to each of the semiconductor packages 4200.

FIG. 22 is a schematic view illustrating an embodiment of a memory card 5000 according to an aspect of the inventive concept.

Referring to FIG. 22, a controller 5100 and a memory 5200 are disposed to send/receive electric signals to/from each other. For example, when the controller 5100 gives a command to the memory 5200, the memory 5200 can send data. The memory 5200 can include a semiconductor device formed by a method according to exemplary embodiments of the inventive concept. The semiconductor devices according to the various embodiments of the inventive concept can be disposed in architecture memory arrays in correspondence to the logic gate design. The memory arrays disposed in a plurality of rows and columns can have one or more memory array bank. The memory 5200 can include the memory array or the memory array bank. The memory card 5000 can further include conventional members, such as a row decoder, a column decoder, input/output (I/O) buffers, and/or a control register in order to drive the memory array bank. The memory card 5000 can be used in memory devices as a memory card, for example, such as a memory stick card, a smart media (SM) card, a secure digital (SD) card, a mini SD card, or a multi media card (MMC).

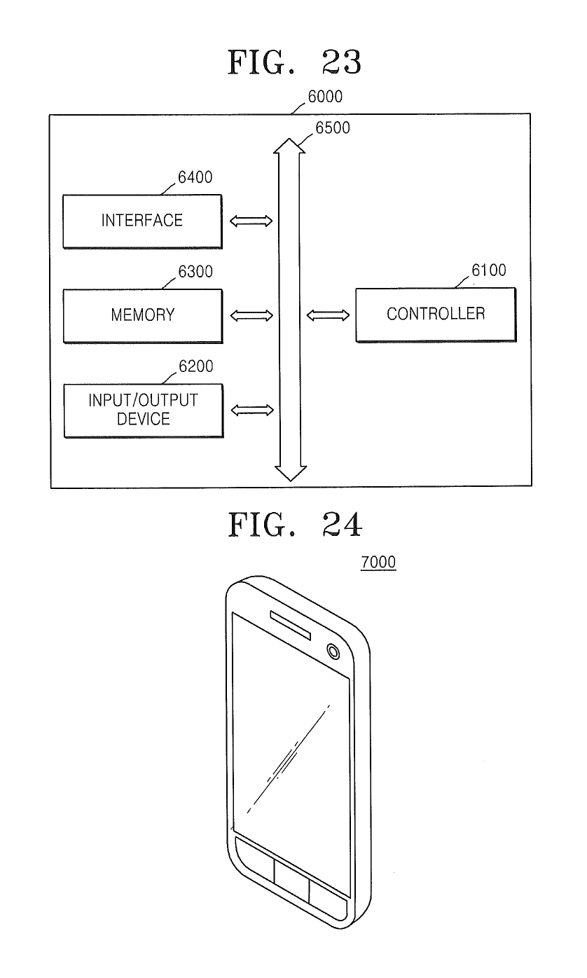

FIG. 23 is a schematic diagram of a system 6000 according to an aspect of the inventive concept.

Referring to FIG. 23, the system 6000 may include a controller 6100, an input/output device 6200, a memory 6300, and an interface 6400. The system 6000 may be a mobile system or a system that transmits or receives data. The mobile system may be a personal digital assistant (PDA), a portable computer, a web tablet, a wireless phone, a mobile phone, a digital music player, or a memory card. The controller 6100 executes a software program and controls the system 6000. The controller 6100 may be a microprocessor, a digital signal processor, a microcontroller, or the like. The input/output device 6300 can be used to input or output data of the system 6000. The system 6000 is connected to an external apparatus, for example, a personal computer or a network, using the input/output device 6200, to send/receive data to/from the external apparatus. The input/output device 6200 may be a keypad, a keyboard, or a display. The memory 6300 may store codes and/or data for operating the controller 6100 and/or may store data processed by the controller 6100. The memory 6300 may include a semiconductor device formed by a method according to exemplary embodiments of the inventive concept. The interface 6400 may be a data transmission path between the system 6000 and an external apparatus. The controller 6100, the input/output device 6200, the memory 6300, and the interface 6400 may communicate with one another by a bus 6500. For example, the system 6000 can be used for a mobile phone, a MP3 player, a navigation system, a portable multimedia player (PMP), a solid state disk (SSD), or a household appliance.

FIG. 24 is a perspective view of an electronic device 7000 to which a semiconductor device according to an embodiment of the inventive concept is applicable.

Referring to FIG. 24, the electronic system 7000 is a case in which the electronic system 5000, 6000 is applied to a mobile phone. Besides the mobile phone, the electronic system 5000, 6000 may also be applicable to an MP3 player, a navigation device, a portable multimedia player (PMP), a solid state disk (SSD), a vehicle, or household appliances.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed:

1. A semiconductor device comprising:
a device layer;
a lower conductive layer electrically connected to the device layer;
a lower barrier layer surrounding the lower conductive layer;
an upper conductive layer disposed on the lower conductive layer, and electrically connected to the lower conductive layer; and
an upper barrier layer surrounding the upper conductive layer, and comprising a material that is different from a material included in the lower barrier layer.

2. The semiconductor device of claim 1, wherein the lower barrier layer is disposed on side walls and a bottom of the lower conductive layer.

3. The semiconductor device of claim 1, wherein the upper barrier layer is disposed on side walls and a part on a bottom of the upper conductive layer.

4. The semiconductor device of claim 1, wherein the lower barrier layer comprises a conductive material.

5. The semiconductor device of claim 1, wherein the lower barrier layer comprises ruthenium (Ru), cobalt (Co), or a combination thereof.

6. The semiconductor device of claim 1, wherein the upper barrier layer comprises an insulating material.

7. The semiconductor device of claim 1, wherein the upper barrier layer comprises manganese silicon oxide.

8. The semiconductor device of claim 1, further comprising:
a first upper interlayer dielectric surrounding the upper barrier layer, wherein the upper barrier layer is formed using a heat process to generate a chemical combination between a material included in the first upper interlayer dielectric and a material included in the upper conductive layer.

9. The semiconductor device of claim 1, wherein a thickness of the upper barrier layer may be equal to or less than a thickness of the lower barrier layer.

10. The semiconductor device of claim 1, wherein the upper conductive layer has a width that is greater than a width of the lower conductive layer.

11. The semiconductor device of claim 1, wherein the lower conductive layer comprises a pillar, and the upper conductive layer comprises lines.

12. The semiconductor device of claim 1, wherein the lower conductive layer and the upper conductive layer form a single body structure.

13. The semiconductor device of claim 1, wherein the upper barrier layer is disposed on the lower barrier layer, and the upper barrier layer has a curved end portion.

14. The semiconductor device of claim 1, wherein a lowermost surface of the upper barrier layer is disposed at a lower level than that of an uppermost surface of the lower barrier layer.

15. A semiconductor device comprising a dual-damascene metallization structure, wherein the dual-damascene metallization structure comprises:
a conductive layer;
a lower barrier layer surrounding a lower portion of the conductive layer, and having a conductivity; and
an upper barrier layer surrounding an upper portion of the conductive layer, disposed on the lower barrier layer, and having an insulating property.

16. A semiconductor device comprising:
a dual damascene conductive structure including a lower conductive layer and an upper conductive layer directly on the lower conductive layer and having a greater width than the lower conductive layer;
an upper barrier layer comprising a first material that partially surrounds the upper conductive layer to separate the upper conductive layer from an upper interlayer insulating layer in which the upper conductive layer is located; and
a lower barrier layer comprising a second material, different from the first material, that partially surrounds the lower conductive layer to separate the lower conductive layer from a lower interlayer insulating layer in which the lower conductive layer is located.

17. The semiconductor device of claim 16 wherein a thickness of a side wall of the lower barrier layer that separates the lower conductive layer from the lower interlayer insulating layer is greater than a thickness of a side wall of the upper barrier layer that separates the upper conductive layer from the upper interlayer insulating layer.

18. The semiconductor device of claim 17 wherein the first material comprises an insulating material and the second material comprises a conductive material.

19. The semiconductor device of claim 16 wherein a portion of the upper barrier layer that contacts the lower barrier layer is curved.

20. The semiconductor device of claim 17 wherein a lower edge of the upper barrier layer extends beyond an interface of the upper and lower interlayer insulating layers.

21. The semiconductor device of claim 16 wherein the upper and lower conductive layers comprise a damascene unitary body structure.
